(19) United States
(12) Patent Application Publication
(10) Pub. No.: US 2025/0378212 A1
(43) Pub. Date: Dec. 11, 2025

(54) ELEVATOR INFORMATION PROVIDING DEVICE AND ELEVATOR INFORMATION PROVIDING METHOD

(71) Applicant: Mitsubishi Electric Corporation, Tokyo (JP)

(72) Inventors: Reiko SAKATA, Tokyo (JP); Saki MATSUI, Tokyo (JP); Ryuta ENDO, Tokyo (JP)

(73) Assignee: Mitsubishi Electric Corporation, Tokyo (JP)

(21) Appl. No.: 19/302,098

(22) Filed: Aug. 18, 2025

Related U.S. Application Data
(63) Continuation of application No. PCT/JP2023/015335, filed on Apr. 17, 2023.

(51) Int. Cl. G06F 30/12; G06F 30/13

(52) U.S. Cl. CPC G06F 30/12; G06F 30/13

(57) ABSTRACT

An objective is to obtain an elevator information providing device that provides information indicating the relationship between an elevator and a target to be carried by the elevator. The elevator information providing device includes: a building data acquiring unit that acquires data of a building; a selection unit that selects an elevator suitable for installation in the building from a plurality of elevators, using the data of the building; and an image data acquiring unit that acquires data of an image including the elevator selected by the selection unit and a target to be carried by the elevator, and outputs the acquired data of the image.

### CROSS-REFERENCE TO RELATED APPLICATION

This application is a continuation of International Patent Application No. PCT/JP2023/015335, filed on Apr. 17, 2023, the entire contents of which are incorporated herein by reference.

### TECHNICAL FIELD

The present invention relates to an elevator information providing device and an elevator information providing method.

### BACKGROUND ART

An architectural designer who is on the elevator ordering side acquires information regarding an elevator using an elevator information providing device, and then orders an elevator that meets his/her request.

The architectural designer inputs the purpose of use of the building, the number of floors of the building, an estimated resident population per floor, and the specification required for an elevator to the elevator information providing device, and thus, can obtain a CAD symbol of the elevator (Patent Literature 1, for example).

### CITATION LIST

### Patent Literature

Patent Literature 1: JP 2002-230253 A

### SUMMARY OF INVENTION

### Technical Problem

Such an elevator information providing device can obtain a CAD symbol of an elevator, but does not provide information indicating the relationship between the elevator and a target to be carried by the elevator. Therefore, it is difficult for the user of the elevator information providing device to imagine how an elevator would look like when actually installed, and the user of the elevator information providing device may be confused when selecting an elevator.

The present invention has been made to solve the problem described above, and an object thereof is to obtain an elevator information providing device that provides information indicating the relationship between an elevator and a target to be carried by the elevator.

### Solution to Problem

An elevator information providing device according to the present invention includes processing circuitry to acquire data of a building, to perform selection of an elevator suitable for installation in the building from a plurality of elevators, using the data of the building, and to acquire data of an image including the elevator selected by the selection and a target to be carried by the elevator, and output the acquired data of the image, wherein the data of the building includes a plurality of pieces of data including data of a region in which the building is to be built, and in the selection, the elevator is selected using data generated by respectively assigning weights to the plurality of pieces of data of the building.

### Advantageous Effects of Invention

An elevator information providing device according to the present invention can provide information indicating the relationship between an elevator and a target to be carried by the elevator. This is because data of an image including the elevator selected by a selection unit and the target to be carried by the elevator is output.

### BRIEF DESCRIPTION OF DRAWINGS

FIG. 1 is a diagram for explaining an application example of an elevator information providing device according to a first embodiment of the present invention.

FIG. 2 is a configuration diagram of the elevator information providing device according to the first embodiment of the present invention.

FIG. 3 is a diagram illustrating an example of a WEB site created by the elevator information providing device according to the first embodiment of the present invention.

FIG. 4 is a flowchart showing an elevator information providing method using the elevator information providing device according to the first embodiment of the present invention.

FIG. 5 is a diagram for explaining an example of data of an image to be output by the elevator information providing device according to the first embodiment of the present invention.

FIG. 6 is a diagram for explaining another example of data of an image to be output by the elevator information providing device according to the first embodiment of the present invention.

FIG. 7 is a diagram for explaining yet another example of data of an image to be output by the elevator information providing device according to the first embodiment of the present invention.

FIG. 8 is a diagram for explaining still another example of data of an image to be output by the elevator information providing device according to the first embodiment of the present invention.

FIG. 9 is a configuration diagram of an elevator information providing device according to a second embodiment of the present invention.

### DESCRIPTION OF EMBODIMENTS

### First Embodiment

First, an application example of an elevator information providing device 100 according to a first embodiment of the present invention is described. The elevator information providing device 100 according to the present embodiment is based on the assumption that the user is an architectural designer, but the user is not limited to this and may be any person who considers purchasing or ordering an elevator. Note that, in a case where the user is simply mentioned in the following description, the user means a person who considers purchasing or ordering an elevator and is the user of the elevator information providing device 100, and a user of the elevator is called a passenger.

The elevator information providing device 100 according to the present embodiment creates part of a WEB site that provides elevator information. That is, the user of the elevator information providing device 100 is a user of a WEB site created by the elevator information providing device 100. The WEB site created by the elevator information providing device 100 provides elevator information when data of the building in which an elevator is to be installed or data of a specification required for the elevator is input by the user.

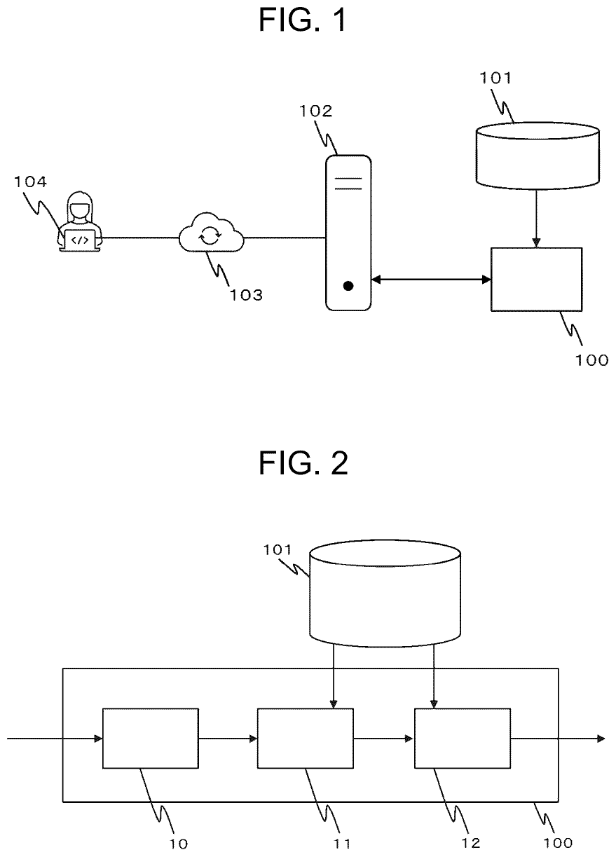

FIG. 1 is a diagram for explaining an application example of the elevator information providing device 100 according to the first embodiment of the present invention. The elevator information providing device 100 according to the present embodiment provides the user with elevator information via a server 102 and an Internet line 103. FIG. 1 is explained in line with the flow of data. As illustrated in FIG. 1, the user's personal computer 104 is connected to the server 102 via the Internet line 103. Building data the user has input to the personal computer 104 is input to the elevator information providing device 100 through the server 102. Using data of the building, the elevator information providing device 100 selects an elevator suitable for installation in the building from a plurality of elevators stored in a storage device 101. The elevator information providing device 100 then acquires data of an image including the selected elevator and a target to be carried by the elevator from data of images stored in the storage device 101, and outputs the acquired data of the image.

The data output from the elevator information providing device 100 is input to the personal computer 104 of the user through the server 102, and the image including the elevator selected by the elevator information providing device 100 and the target to be carried by the elevator is displayed on the personal computer 104. That is, the WEB site created by the elevator information providing device 100 is a WEB site in which an elevator suitable for installation in the building is selected in response to an input of the data of the building by the user, and an image including the selected elevator and the target to be carried by the elevator is displayed.

Next, the configuration of the elevator information providing device 100 according to the first embodiment of the present invention is described. FIG. 2 is a configuration diagram of the elevator information providing device 100 according to the first embodiment of the present invention. As illustrated in FIG. 2, the elevator information providing device 100 according to the present embodiment includes: a building data acquiring unit 10 that acquires data of the building; a selection unit 11 that selects an elevator suitable for installation in the building from a plurality of elevators, using the data of the building; and an image data acquiring unit 12 that acquires data of an image including the elevator selected by the selection unit 11 and a target to be carried by the elevator, and outputs the acquired data of the image. Note that data of the plurality of elevators is stored in the storage device 101.

The building data acquiring unit 10 acquires, through the server 102, the data of the building the user of the elevator information providing device 100 has input to the user's personal computer 104. For example, in a case where the user is an architectural designer who is going to build a building, the user inputs data of the building to be built, to the personal computer 104. The data of the to-be-built building that has been input to the personal computer 104 is acquired by the building data acquiring unit 10 of the elevator information providing device 100 through the server 102.

The data of the building includes data of the region in which the building is to be built, data of the type of the building, data of the number of floors of the building, data of the number of persons who will use the elevator, data of the size of the building, and data as to whether or not it is necessary to take measures for welfare in the building, for example. The WEB site created by the elevator information providing device 100 has items to which the region in which the building is to be built, the type of the building, the number of floors of the building, the number of persons who will use the elevator, the size of the building, whether or not welfare measures are necessary in the building, and the like are input, and the building data acquiring unit 10 acquires the data input to these items.

Using the data of the building acquired by the building data acquiring unit 10, the selection unit 11 selects an elevator suitable for installation in the building from the plurality of elevators stored in the storage device 101. After selecting an elevator suitable for installation in the building from the plurality of elevators, the selection unit 11 notifies the image data acquiring unit 12 of the selected elevator.

In the present embodiment, the method by which the selection unit 11 selects an elevator is not limited to any particular method. For example, the selection unit 11 may select an elevator, using a trained model for inferring an elevator suitable for installation in the building from the data of the building. Specifically, the selection unit 11 may acquire, from the storage device 101, a trained model for inferring an elevator suitable for installation in the building from the data of the building, input the data of the building acquired by the building data acquiring unit 10 to the trained model, and infer and select an elevator suitable for installation in the building. Other than that, a specification data acquiring unit that acquires data of a specification required for an elevator may be added to the configuration of the elevator information providing device 100, and an elevator suitable for installation in the building may be selected from the plurality of elevators stored in the storage device 101, using the data of the building and the data of the specification required for the elevator.

In the present embodiment, the selection unit 11 may select one type of elevator, or two or more types of elevators. In a case where the selection unit 11 selects one type of elevator, the selection unit 11 selects an elevator most suitable for installation in the building. In a case where two or more types of elevators are to be selected by the selection unit 11, the selection unit 11 may select elevators suitable for installation in the building in order of recommendation, or without any order of recommendation. In a case where a selection has been made with order of recommendation given to elevators suitable for installation in the building, the selection unit 11 outputs the selected elevators, together with the order of recommendation. In a case where a selection has been made without order of recommendation given to elevators suitable for installation in the building, only the selected elevators are output.

Further, the method by which the selection unit 11 selects an elevator suitable for installation in the building may include a method by which the selection unit 11 presents two or more types of elevators to the user, and the user selects one of them. In this case, before notifying the image data acquiring unit 12 of the selected elevators, the selection unit 11 provides the user with information about two or more types of elevators, and obtains the information selected by the user. Further, if the selection unit 11 can select an elevator suitable for installation in the building from a plurality of elevators, the number of pieces of the data of the building to be acquired by the building data acquiring unit 10 is not limited to any particular number either.

The image data acquiring unit 12 acquires data of an image including the elevator selected by the selection unit 11 and a target to be carried by the elevator, and outputs the acquired data of the image. The data of the image is stored in the storage device 101, and the image data acquiring unit 12 acquires, from the storage device 101, the data of the image including the elevator selected by the selection unit 11 and the target to be carried by the elevator. The target to be carried by the elevator is a person or an object to be carried by the elevator. The person to be carried by the elevator is a person who uses the elevator, and is a passenger of the elevator. The object to be carried by the elevator is a robot or a wheelchair that is boarded on and off the elevator, or goods such as a cardboard box. In a case where the elevator selected by the selection unit 11 is not for passengers but for goods, the object to be carried by the elevator may be a vehicle such as a forklift, may be goods such as a cardboard box, or may be a cart for carrying goods.

The data of the image output from the image data acquiring unit 12 is input to the personal computer 104 of the user of the elevator information providing device 100. Accordingly, a display device of the personal computer 104 displays an image including the elevator selected by the selection unit 11 and the target to be carried by the elevator. Since the image including the elevator selected by the selection unit 11 and the target to be carried by the elevator are displayed on the display device in the present embodiment, data in a data format that is not normally called an image, such as a CAD drawing whose data format is DWG, DXF, or the like, or PDF is also regarded as an image.

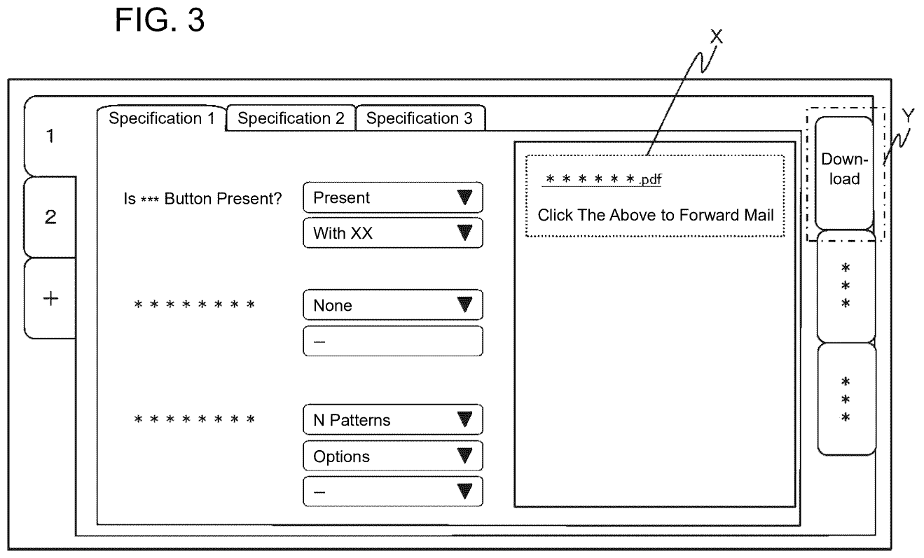

FIG. 3 is a diagram illustrating an example of a WEB site created by the elevator information providing device 100 according to the first embodiment of the present invention. Referring to FIG. 3, a method for displaying data of an image output by the elevator information providing device 100 according to the present embodiment is described. When an elevator is selected by the selection unit 11, an image including the elevator selected by the selection unit 11 and a target to be carried by the elevator may be displayed on the display device as it is without any operation performed by the user of the elevator information providing device 100, but it is not limited thereto. For example, an operation button for displaying an image including the elevator selected by the selection unit 11 and the target to be carried by the elevator may be displayed when pressed by the user of the elevator information providing device 100.

Other than that, as illustrated in a portion X surrounded by a dotted line in FIG. 3, an image including the elevator selected by the selection unit 11 and the target to be carried by the elevator may be displayed as a link that can be sent by e-mail, for example. Further, as illustrated in a portion Y surrounded by a dot-and-dash line in FIG. 3, an image including the elevator selected by the selection unit 11 and the target to be carried by the elevator may be displayed as an operation button with which downloading can be conducted. Also, the operation button with which downloading can be conducted may be an operation button with which the image including the elevator selected by the selection unit 11 and the target to be carried by the elevator can be printed out. It is assumed that, in any display manner, the data of the image including the elevator selected by the selection unit 11 and the target to be carried by the elevator is displayed.

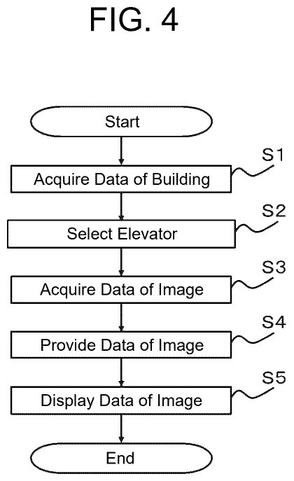

Next, an elevator information providing method using the elevator information providing device 100 according to the present embodiment is described. FIG. 4 is a flowchart showing an elevator information providing method using the elevator information providing device 100 according to the first embodiment of the present invention. As shown in FIG. 4, the elevator information providing method using the elevator information providing device 100 includes: a data acquiring step S1 of acquiring data of the building; a selection step S2 of selecting an elevator suitable for installation in the building from a plurality of elevators, using the data of the building; an image acquiring step S3 of acquiring and outputting data of an image including the elevator selected in the selection step S2 and the target to be carried by the elevator; a provision step S4 of providing the user with the output data of the image; and a display step S5 of displaying the provided data of the image on the personal computer 104 of the user.

The data acquiring step S1 is a step of acquiring the data of the building. In the data acquiring step S1, the building data acquiring unit 10 acquires, through the server 102, the data of the building that has been input to the personal computer 104 by the user of the elevator information providing device 100. The building data acquiring unit 10 then outputs the acquired data of the building to the selection unit 11. After completion of the data acquiring step S1, the elevator information providing method using the elevator information providing device 100 in the present embodiment proceeds to the selection step S2.

The selection step S2 is a step of selecting an elevator suitable for installation in the building from a plurality of elevators, using the data of the building. In the selection step S2, using the data of the building acquired in the data acquiring step S1, the selection unit 11 selects an elevator suitable for installation in the building from the plurality of elevators stored in the storage device 101. Note that, in the present embodiment, the method by which the selection unit 11 selects an elevator is not limited to any particular method, as mentioned above. After selecting an elevator, the selection unit 11 notifies the image data acquiring unit 12 of the selected elevator. After completion of the selection step S2, the elevator information providing method using the elevator information providing device 100 in the present embodiment proceeds to the image acquiring step S3.

The image acquiring step S3 is a step of acquiring data of an image including the elevator selected in the selection step S2 and the target to be carried by the elevator, and outputting the acquired data of the image. In the image acquiring step S3, the image data acquiring unit 12 acquires, from the storage device 101, the data of the image including the elevator selected in the selection step S2 and the target to be carried by the elevator, and outputs the acquired data of the image. After completion of the image acquiring step S3, the elevator information providing method using the elevator information providing device 100 in the present embodiment proceeds to the provision step S4.

The provision step S4 is a step of providing the user with the data of the image, which has been output from the image data acquiring unit 12. In the provision step S4, the server 102 provides, via the Internet line 103, the user with the data of the image, which has been output by the image data acquiring unit 12. That is, in the provision step S4, the data of the image, which has been output from the elevator information providing device 100, is provided to the user via the server 102 and the Internet line 103. After completion of the provision step S4, the elevator information providing method using the elevator information providing device 100 in the present embodiment proceeds to the display step S5.

The display step S5 is a step of displaying the provided data of the image on the personal computer 104 of the user. In the display step S5, the personal computer 104 of the user displays the data of the image, which has been provided from the server 102 via the Internet line 103. As described above, when an elevator is selected by the selection unit 11, the image including the elevator selected by the selection unit 11 and the target to be carried by the elevator may be displayed on the display device as it is without any operation performed by the user of the elevator information providing device 100 in the present embodiment, but it is not limited thereto.

As the image including the elevator selected by the selection unit 11 and the target to be carried by the elevator is displayed on the personal computer 104, the user can obtain information indicating the relationship between the elevator and the target to be carried by the elevator. After completion of the display step S4, the elevator information providing method using the elevator information providing device 100 in the present embodiment comes to an end.

As described above, the elevator information providing device 100 according to the present embodiment can provide information indicating the relationship between an elevator and the target to be carried by the elevator. This is because the image data acquiring unit 12 outputs data of an image including the elevator selected by the selection unit 11 and the target to be carried by the elevator. As the elevator information providing device 100 according to the present embodiment provides information indicating the relationship between the elevator and the target to be carried by the elevator, the user of the elevator information providing device 100 according to the present embodiment can more easily imagine the elevator after installation. The user of the elevator information providing device 100 according to the present embodiment can refer to the information indicating the relationship between the elevator and the target to be carried by the elevator, in introducing the selected elevator.

Next, an image including the elevator selected by the selection unit 11 and the target to be carried by the elevator is described in detail below. As described above, in the present embodiment, the image including the elevator selected by the selection unit 11 and the target to be carried by the elevator includes an image in a data format that is not normally called an image, such as a CAD drawing whose data format is DWG, DXF, or the like, or PDF. There is a plurality of types of images including the elevator selected by the selection unit 11 and the target to be carried by the elevator. In the description below, specific examples thereof are described one by one but are merely examples, and images are not limited thereto in the present embodiment.

The first one is an image in which a drawing of a wheelchair user to be carried by the elevator is included in a CAD drawing of the elevator selected by the selection unit 11. The CAD drawing of the elevator selected by the selection unit 11 is a hoistway plan view or an installation view, for example. The image in which a drawing of a wheelchair user to be carried by the elevator is included in a CAD drawing of the elevator selected by the selection unit 11 is an image in which a drawing showing the wheelchair user is placed in the car space shown in a hoistway plan view of the elevator, for example. The car space is the space in which a passenger stays after getting on the elevator. Also, the image in which a drawing of a wheelchair user to be carried by the elevator is included in a CAD drawing of the elevator selected by the selection unit 11 may be an image in which a drawing showing the wheelchair user is placed at the doorway of the elevator shown in a hoistway plan view of the elevator, or may be an image in which a drawing showing the wheelchair user is placed next to the car of the elevator shown in an installation view of the elevator.

As the elevator information providing device 100 according to the present embodiment outputs the data of the image in which a drawing of a wheelchair user to be carried by the elevator is placed in a CAD drawing of the elevator selected by the selection unit 11, it is possible to provide information indicating the relationship between the elevator and the wheelchair user to be carried by the elevator. Thus, the user of the elevator information providing device 100 according to the present embodiment can imagine how the wheelchair user will move after the elevator is actually installed.

Movement of the wheelchair user after the elevator is actually installed is a motion at a time when the wheelchair user enters and exits the elevator, a motion at a time when the wheelchair user presses a floor button in the car space of the elevator, or the like. If a motion of the wheelchair user entering or exiting the elevator can be imagined, it can be understood whether or not the doorway width of the elevator is designed to have a margin, or whether or not the doorway width is so small that a wheel of the wheelchair bumps into an object. Also, if a motion of the wheelchair user pressing a floor button in the car space of the elevator can be imagined, it can be understood whether or not the operation panel having the floor buttons is located within the wheelchair user's reach.

The second one is an image including the elevator selected by the selection unit 11 and the target to be carried by the elevator, and is an image showing how the target to be carried by the elevator enters or exits the elevator. Here, the image showing how the target to be carried by the elevator enters or exits the elevator may be a still image or a video from which the time sequence of motions can be seen. Furthermore, the still image may be a still image at a certain point of time, or may be a still image from which the time sequence of motions can be seen.

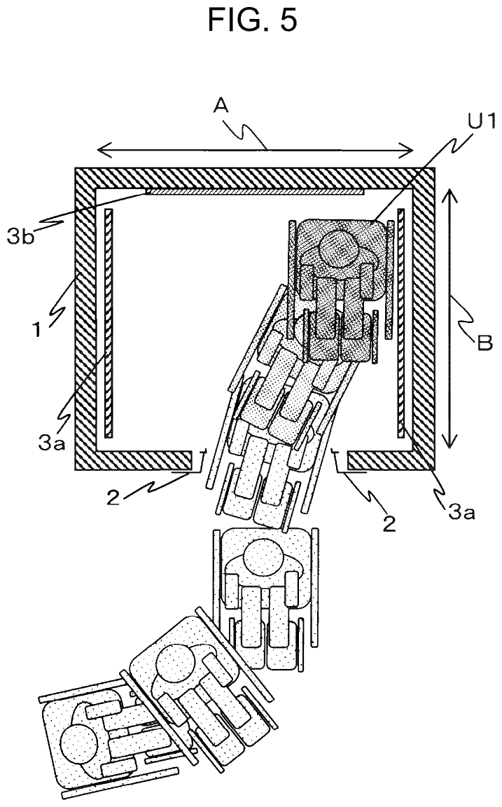

FIG. 5 is a diagram for explaining an example of data of an image to be output by the elevator information providing device 100 according to the first embodiment of the present invention. FIG. 5 is an example of a cross-sectional view of the elevator as viewed from above, and illustrates a simplified view generally called a hoistway plan view, showing an internal dimension A×B of the car. In the elevator illustrated in FIG. 5, the car space is formed with a car member 1, and includes handrails 3a and a mirror 3b. A wheelchair user U1 who is a user of the elevator gets on and off the elevator from an elevator hall formed with an elevator hall member 2. Note that the elevator illustrated in FIG. 5 only needs to be shown in such a manner that the size of the car space can be recognized, and therefore, the car space is not necessarily formed with the car member 1.

An image that includes the elevator selected by the selection unit 11 and the target to be carried by the elevator, and shows how the target enters or exits the elevator is a still image showing how the wheelchair user U1 to be carried by the elevator exits the elevator selected by the selection unit 11, as illustrated in FIG. 5, for example. FIG. 5 illustrates the motion of the wheelchair user U1 exiting the elevator, which is the motion of the wheelchair user U1 getting off the elevator. FIG. 5 is a still image illustrating a simulation video of the wheelchair user U1 entering or exiting the elevator.

In FIG. 5, the motion of the wheelchair user U1 exiting the elevator is represented by a plurality of drawings of the wheelchair user U1, in some of which different colors are used. In FIG. 5, the position of the wheelchair user U1 shown in the darkest color indicates the position of the wheelchair user U1 staying in the elevator car, which is the position of the wheelchair user U1 starting the movement of getting off the elevator. In FIG. 5, the wheelchair user U1 shown in the darkest color moves to the position of the wheelchair user U1 shown in the second darkest color.

That is, in FIG. 5, the direction in which the wheelchair user U1 advances is represented by a plurality of colors of the wheelchair user U1, which become gradually paler, and the color of the wheelchair user U1 becomes paler as the wheelchair user U1 advances. Note that, in FIG. 5, the color shades are indicated by dots for convenience, and the portion with the highest dot density represents the darkest color.

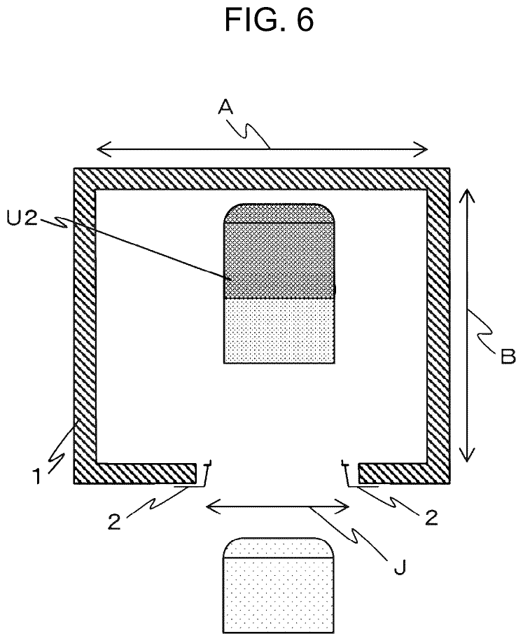

FIG. 6 is a diagram for explaining another example of data of an image to be output by the elevator information providing device 100 according to the first embodiment of the present invention. Like FIG. 5, FIG. 6 is an example of a cross-sectional view of the elevator as viewed from above, and illustrates a simplified view generally called a hoistway plan view, showing an internal dimension A×B of the car and a width J of the doorway. A robot U2 that is a user of the elevator gets on and off the elevator from the elevator hall formed with the elevator hall member 2. Like the elevator illustrated in FIG. 5, the elevator illustrated in FIG. 6 only needs to be shown in such a manner that the size of the car space can be recognized, and therefore, the car space is not necessarily formed with the car member 1.

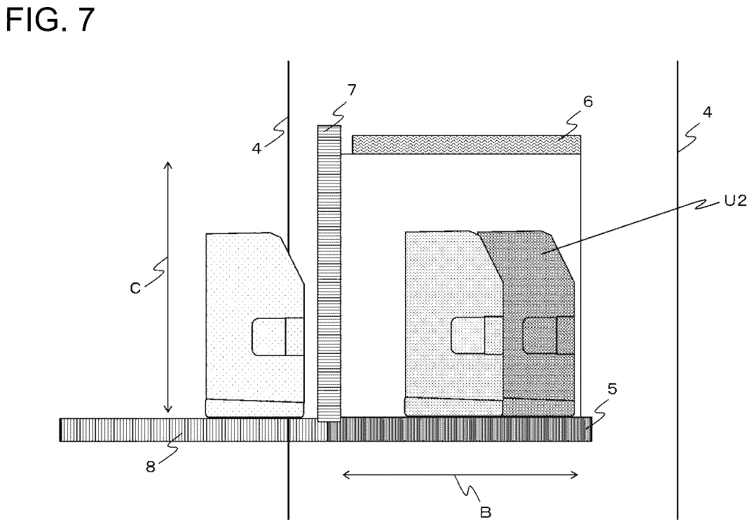

FIG. 7 is a diagram for explaining yet another example of data of an image to be output by the elevator information providing device 100 according to the first embodiment of the present invention. FIG. 7 is an example of a cross-sectional view of the elevator as viewed from the side, and illustrates a simplified view generally called a hoistway cross-sectional view, showing a depth B of the car and a height C of the car. The elevator illustrated in FIG. 7 moves up and down the hoistway formed with a hoistway member 4. In the elevator illustrated in FIG. 7, the car space is formed with a car floor member 5, a car ceiling member 6 including lighting and an air conditioner, and a door member 7. The door member 7 includes a hall door and a doorcase thereof, and a car door and a doorcase thereof. The robot U2, which is a user of the elevator, gets on and off the elevator from an elevator hall formed with a building floor member 8. Note that the elevator illustrated in FIG. 7 only needs to be shown in such a manner that the size of the car space can be recognized, and therefore, the car space is not necessarily formed with the car floor member 5, the car ceiling member 6, and the door member 7.

An image that includes the elevator selected by the selection unit 11 and the target to be carried by the elevator, and shows how the target enters or exits the elevator is a still image showing how the robot U2 to be carried by the elevator exits the elevator selected by the selection unit 11, as illustrated in FIG. 6 or 7, for example. FIGS. 6 and 7 illustrate the motion of the robot U2 exiting the elevator, which is the motion of the robot U2 getting off the elevator. FIGS. 6 and 7 are still images each illustrating a simulation video of the robot U2 entering or exiting the elevator.

In FIGS. 6 and 7, the motion of the robot U2 exiting the elevator is represented by a plurality of drawings of the robot U2, in some of which different colors are used, as in FIG. 5. That is, in FIGS. 6 and 7, the direction in which the robot U2 advances is represented by a plurality of colors of the robot U2, which become gradually paler, and the color of the robot U2 becomes paler as the robot U2 advances. Note that, in FIGS. 6 and 7, the color shades are also indicated by dots for convenience, and the portion with the highest dot density represents the darkest color.

Other than that, an image that includes the elevator selected by the selection unit 11 and the target to be carried by the elevator, and shows how the target enters or exits the elevator may be a still image showing how a vehicle to be carried by the elevator enters or exits the elevator selected by the selection unit 11, for example.

Also, an image that includes the elevator selected by the selection unit 11 and the target to be carried by the elevator, and shows how the target enters or exits the elevator may be a video, and, for example, may be a simulation video showing how a wheelchair user to be carried by the elevator enters or exits the elevator selected by the selection unit 11, or a simulation video showing how an elderly person to be carried by the elevator enters or exits the elevator selected by the selection unit 11. Other than that, an image showing how the target to be carried by the elevator enters or exits the elevator may be a simulation video showing how a robot to be carried by the elevator enters or exits the elevator selected by the selection unit 11.

The elevator information providing device 100 according to the present embodiment outputs data of an image that includes the elevator selected by the selection unit 11 and the target to be carried by the elevator and shows how the target enters or exits the elevator, and accordingly, can provide information that indicates the relationship between the elevator and the target to be carried by the elevator, and also indicates how the target enters or exits the elevator. Thus, the user of the elevator information providing device 100 according to the present embodiment can imagine how the target will move to enter and exit the elevator after the elevator is actually installed.

In particular, when the elevator information providing device 100 according to the present embodiment outputs data of a simulation video that is an image including the elevator selected by the selection unit 11 and a wheelchair user to be carried by the elevator and shows how the wheelchair user enters or exits the elevator, the user of the elevator information providing device 100 according to the present embodiment can imagine how the wheelchair user will move to enter or exit the elevator after the elevator is actually installed. For example, it is possible to imagine whether there is a space for the wheelchair user to change directions after getting on the elevator. Other than that, in a case where the wheelchair user does not change directions after getting on the elevator, the wheelchair user is to get off the elevator backward. However, if a mirror is installed in the elevator, it is possible to imagine the wheelchair user being able to easily get off the elevator.

Further, when the elevator information providing device 100 according to the present embodiment outputs data of a simulation video that is an image including the elevator selected by the selection unit 11 and an elderly person to be carried by the elevator and shows how the elderly person enters or exits the elevator, the user of the elevator information providing device 100 according to the present embodiment can imagine how the elderly person will move to enter or exit the elevator after the elevator is actually installed. For example, it is possible to imagine that an elderly person using a cane can easily enter and exit the elevator if there is a handrail in the elevator. Also, it is possible to imagine that an elderly person who walks slowly can easily enter and exit the elevator if the open time of the elevator is long.

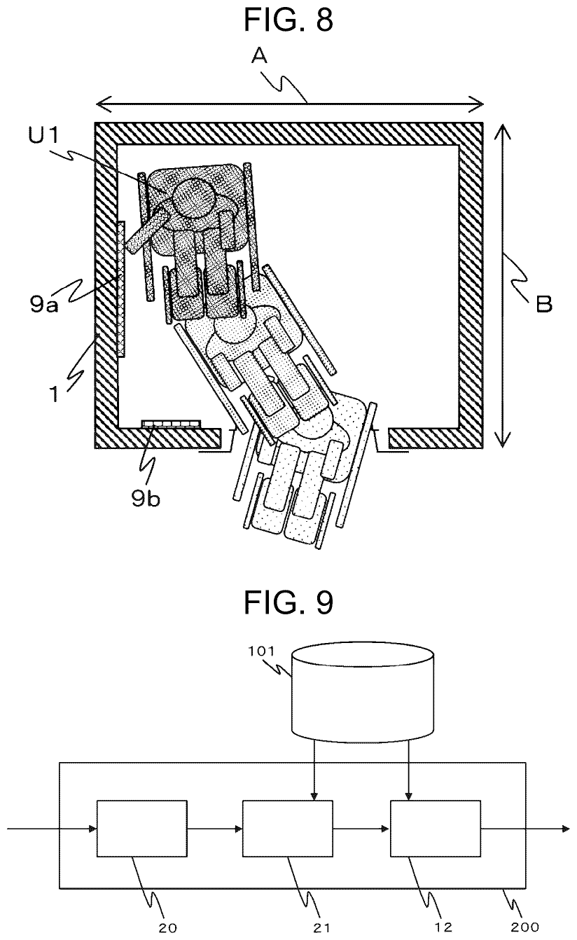

The third one is an image including the elevator selected by the selection unit 11 and the target to be carried by the elevator, and is an image showing how the target operates the elevator. Here, the image showing how the target operates the elevator may be a still image or may be a video. FIG. 8 is a diagram for explaining yet another example of data of an image to be output by the elevator information providing device 100 according to the first embodiment of the present invention. FIG. 8 is an example of a cross-sectional view of the elevator as viewed from above, and illustrates a simplified view generally called a hoistway plan view, showing an internal dimension A×B of the car. The elevator illustrated in FIG. 8 includes a wheelchair-dedicated operation panel 9a and a wing-wall operation panel 9b. Like the elevators illustrated in FIGS. 5 and 6, the elevator illustrated in FIG. 8 only needs to be shown in such a manner that the size of the car space can be recognized, and therefore, the car space is not necessarily formed with the car member 1.

An image that includes the elevator selected by the selection unit 11 and the target to be carried by the elevator, and shows how the target operates the elevator is a still image showing how the wheelchair user U1 to be carried by the elevator operates the elevator, as illustrated in FIG. 8, for example. FIG. 8 illustrates the motion of the wheelchair user U1 operating the elevator and the motion of the wheelchair user U1 exiting the elevator after the operation, which are the motions of the wheelchair user U1 operating the elevator and getting off the elevator. FIG. 8 is a still image illustrating a simulation video of the wheelchair user U1 operating the elevator.

In FIG. 8, the motion of the wheelchair user U1 exiting the elevator is represented by a plurality of drawings of the wheelchair user U1, in some of which different colors are used, as in FIG. 5. That is, in FIG. 8, the direction in which the wheelchair user U1 advances is represented by a plurality of colors of the wheelchair user U1, which become gradually paler, and the color of the wheelchair user U1 becomes paler as the wheelchair user U1 advances. Note that, in FIG. 8, the color shades are also indicated by dots for convenience, and the portion with the highest dot density represents the darkest color.

Other than that, an image that includes the elevator selected by the selection unit 11 and the target to be carried by the elevator, and shows how the target operates the elevator may be a simulation video showing how a wheelchair user to be carried by the elevator operates the elevator, a simulation video showing how a robot to be carried by the elevator operates the elevator, or a simulation video showing how a child to be carried by the elevator operates the elevator, for example.

The elevator information providing device 100 according to the present embodiment outputs data of an image that includes the elevator selected by the selection unit 11 and the target to be carried by the elevator and shows how the target operates the elevator, and accordingly, can provide information that indicates the relationship between the elevator and the target to be carried by the elevator, and also indicates how the target operates the elevator. Thus, the user of the elevator information providing device 100 according to the present embodiment can imagine how the target will move to operate the elevator after the elevator is actually installed.

In particular, when the elevator information providing device 100 according to the present embodiment outputs data of a simulation video that is an image including the elevator selected by the selection unit 11 and a wheelchair user to be carried by the elevator and shows how the wheelchair user operates the elevator, the user of the elevator information providing device 100 according to the present embodiment can imagine how the wheelchair user will move to operate the elevator after the elevator is actually installed. For example, it is possible to imagine whether or not the floor buttons are located at such a position that a wheelchair user can easily press them. Of course, it is also possible to imagine whether it is difficult for a wheelchair user to press any of the floor buttons.

Further, when the elevator information providing device 100 according to the present embodiment outputs data of a simulation video that is an image including the elevator selected by the selection unit 11 and a child to be carried by the elevator and shows how the child operates the elevator, the user of the elevator information providing device 100 according to the present embodiment can imagine how the child will move to enter or exit the elevator after the elevator is actually installed. For example, it is possible to imagine whether or not a child with a short height can press all the floor buttons. Of course, it is also possible to imagine whether there is a floor button a child is unable to press.

When an image including the elevator selected by the selection unit 11 and the target to be carried by the elevator as described above is displayed as a drawing on the display device, the elevator selected by the selection unit 11 and the target to be carried by the elevator are displayed on the same screen. That is, when an image including the elevator selected by the selection unit 11 and the target to be carried by the elevator is displayed as a drawing on the display device, the target to be carried by the elevator is displayed near the elevator selected by the selection unit 11. Note that, in an image including the elevator selected by the selection unit 11 and the target to be carried by the elevator, the specific parts of the elevator selected by the selection unit 11 are not necessarily shown, and the elevator only needs to be shown in such a manner that the size of the car space can be recognized.

The fourth one is an image including the elevator selected by the selection unit 11 and the target to be carried by the elevator, and is an image showing the interior design of the elevator selected by the selection unit 11. The elevator information providing device 100 according to the present embodiment outputs data of an image that includes the elevator selected by the selection unit 11 and the target to be carried by the elevator and shows the interior design of the elevator selected by the selection unit 11, and thus, the user of the elevator information providing device 100 more easily imagines the elevator after actual installation, and can consider the harmony between the elevator and the design of the building.

Note that the elevator information providing device 100 is formed with a central processing unit (CPU), for example, but is not limited thereto. The storage device 101 is formed with a read only memory (ROM), a random access memory (RAM), a hard disk drive (HDD), or a semiconductor memory such as a flash memory, but is not limited thereto.

### Second Embodiment

The configuration of an elevator information providing device 200 according to a second embodiment of the present invention is described. The elevator information providing device 200 according to the second embodiment of the present invention has the same application examples as those of the elevator information providing device 100 according to the first embodiment of the present invention. In the second embodiment of the present invention, only the differences from the first embodiment of the present invention are described, and explanation of aspects similar to those of the first embodiment of the present invention is not made herein.

FIG. 9 is a configuration diagram of the elevator information providing device 200 according to the second embodiment of the present invention. As illustrated in FIG. 9, the elevator information providing device 200 according to the present embodiment includes: a building data acquiring unit 20 that acquires data of the building; a selection unit 21 that selects an elevator suitable for installation in the building from a plurality of elevators, using the data of the building; and an image data acquiring unit 12 that acquires data of an image including the elevator selected by the selection unit 21 and a target to be carried by the elevator, and outputs the acquired data of the image. Data of the plurality of elevators is stored in a storage device 101.

The building data acquiring unit 20 acquires, through the server 102, the data of the building the user of the elevator information providing device 200 has input to the user's personal computer 104. The data of the building to be acquired by the building data acquiring unit 20 of the elevator information providing device 200 according to the present embodiment includes a plurality of pieces of data including data of the region in which the building is to be built. For example, the plurality of pieces of data of the building to be acquired by the building data acquiring unit 20 includes data of the region in which the building is to be built, data of the type of the building, data of the number of floors of the building, data of the number of persons who will use the elevator, data of the size of the building, and data as to whether or not it is necessary to take measures for welfare in the building. A WEB site created by the elevator information providing device 200 has items to which the region in which the building is to be built, the type of the building, the number of floors of the building, the number of persons who will use the elevator, the size of the building, whether or not welfare measures are necessary in the building, and the like are input, and the building data acquiring unit 20 acquires the data input to these items.

Using the data of the building acquired by the building data acquiring unit 20, the selection unit 21 selects an elevator suitable for installation in the building from the plurality of elevators stored in the storage device 101. The selection unit 21 of the elevator information providing device 200 according to the present embodiment selects an elevator suitable for installation in the building from the plurality of elevators, using data that is the data of the building and is generated by assigning weights to the respective pieces of the data of the building. Note that, in the present embodiment, the selection unit 21 may select one type of elevator, or two or more types of elevators.

The weights to be assigned to the respective pieces of the data of the building acquired by the building data acquiring unit 20 are now described. In the present embodiment, the data of the building acquired by the building data acquiring unit 20 includes a plurality of pieces of data including data of the region in which the building is to be built, and it is assumed that the building data acquiring unit 20 has acquired five pieces of data that are the data of the region in which the building is to be built, data of the type of the building, data of the number of floors of the building, data of the number of persons who will use the elevator, and data as to whether or not the building needs welfare measures, for example. The selection unit 21 of the elevator information providing device 200 according to the present embodiment selects an elevator suitable for installation in the building from the plurality of elevators stored in the storage device 101, using data generated by assigning weights to the respective pieces of data, which have been acquired by the building data acquiring unit 20 and are the data of the region in which the building is to be built, the data of the type of the building, the data of the number of floors of the building, the data of the number of persons who will use the elevator, and the data as to whether or not the building needs welfare measures.

At this point of time, the selection unit 21 determines that the weight of the greatest value among the weights assigned to the respective pieces of data is the weight assigned to the data of the region in which the building is to be built. Further, the data to which the next highest weight is assigned is the data of the type of the building, the data to which the next highest weight after that is assigned is the data of the number of floors of the building, the data to which the next highest weight after that is assigned is the data of the number of persons who will use the elevator, and the data to which the next highest weight after that is assigned is the data as to whether or not the building needs welfare measures. More specifically, the weight assigned to the data of the number of persons who will use the elevator is equal to or greater than the weight assigned to the data as to whether or not the building needs welfare measures. The weight assigned to the data of the number of floors of the building is equal to or greater than the weight assigned to the data of the number of persons who will use the elevator. The weight assigned to the data of the type of the building is greater than the weight assigned to the data of the number of the floors of the building. The weight assigned to the data of the region in which the building is to be built is greater than the weight assigned to the data of the type of the building. Further, the weights assigned to the respective pieces of data are 1 in total.

Specifically, the selection unit 21 of the elevator information providing device 200 according to the present embodiment selects an elevator suitable for installation in the building from the plurality of elevators, using data generated by assigning a weight of 0.5 to the data of the region in which the building is to be built, a weight of 0.3 to the data of the type of the building, a weight of 0.1 to the data of the number of floors of the building, a weight of 0.05 to the data of the number of persons who will use the elevator, and a weight of 0.05 to the data as to whether or not the building needs welfare measures, for example.

The image data acquiring unit 12 acquires data of an image including the elevator selected by the selection unit 11 and a target to be carried by the elevator, and outputs the acquired data of the image. The data of the image is stored in the storage device 101, and the image data acquiring unit 12 acquires, from the storage device 101, the data of the image including the elevator selected by the selection unit 11 and the target to be carried by the elevator.

The data of the image output from the image data acquiring unit 12 is input to the personal computer 104 of the user of the elevator information providing device 200. Accordingly, the display device of the personal computer 104 displays the elevator selected by the selection unit 21 and the target to be carried by the elevator. Since the elevator selected by the selection unit 21 and the target to be carried by the elevator are also displayed on the display device in the present embodiment, data in a data format that is not normally called an image, such as a CAD drawing whose data format is DWG, DXF, or the like, or PDF is also regarded as an image.

As described above, the elevator information providing device 200 according to the present embodiment can provide the user of the elevator information providing device 200 according to the present embodiment with information about an elevator more suitable for installation in the building than the elevator in the elevator information provided by the elevator information providing device 100 according to the first embodiment of the present invention. This is because the selection unit 21 selects an elevator suitable for installation in the building from the plurality of elevators stored in the storage device 101, using the data generated by assigning weights to the respective pieces of data of the building.

In particular, since the construction site cannot be changed at the stage of considering the elevator for installation in the building, if the weight assigned to the data of the region in which the building is to be built has the greatest value among the weights assigned to the respective pieces of data of the building, it is possible to provide the user of the elevator information providing device 200 according to the present embodiment with more accurate information than the elevator information provided by the elevator information providing device 100 according to the first embodiment of the present invention. Furthermore, in a case where the selection unit 21 selects two or more types of elevators in order of recommendation, the data generated by applying weights to the respective pieces of data of the building is useful in setting the order of recommendation.

In the present invention, the embodiments and modifications can be freely combined with each other, and each of the embodiments can be modified or omitted as appropriate, within the scope of the invention.

### REFERENCE SIGNS LIST

1: car member, 2: elevator hall member, 3a: handrail, 3b: mirror, 4: hoistway member, 5: car floor member, 6: car ceiling member, 7: door member, 8: building floor member, 9a: wheelchair-dedicated operation panel, 9b: wing-wall operation panel, 10, 20: building data acquiring unit, 11, 21: selection unit, 12: image data acquiring unit, 100, 200: elevator information providing device, 101: storage device, 102: server, 103: Internet line, 104: personal computer

1. An elevator information providing device comprising processing circuitry
to acquire data of a building,
to perform selection of an elevator suitable for installation in the building from a plurality of elevators, using the data of the building, and
to acquire data of an image including the elevator selected by the selection and a target to be carried by the elevator, and output the acquired data of the image,
wherein the data of the building includes a plurality of pieces of data including data of a region in which the building is to be built, and
in the selection, the elevator is selected using data generated by respectively assigning weights to the plurality of pieces of data of the building.

2. The elevator information providing device according to claim 1, wherein
the image shows how the target enters or exits the elevator.

3. The elevator information providing device according to claim 1, wherein
the image shows how the target operates the elevator.

4. The elevator information providing device according to claim 1, wherein
the target is a wheelchair user, and
the image is a simulation video showing the wheelchair user entering or exiting the elevator.

5. The elevator information providing device according to claim 1, wherein
the target is a wheelchair user, and
the image is a simulation video showing the wheelchair user operating the elevator.

6. The elevator information providing device according to claim 1, wherein
the target is an elderly person, and
the image is a simulation video showing the elderly person entering or exiting the elevator.

7. The elevator information providing device according to claim 1, wherein
the target is a child, and
the image is a simulation video showing the child operating the elevator.

8. The elevator information providing device according to claim 1, wherein
the image shows interior design of the elevator selected by the selection.

9. The elevator information providing device according to claim 1, wherein
in the selection, a weight assigned to the data of the region in which the building is to be built is determined to have a greatest value among the weights.

10. An elevator information providing method comprising:
acquiring data of a building;
performing selection of an elevator suitable for installation in the building from a plurality of elevators, using the data of the building; and
acquiring data of an image including the elevator selected in the selection and a target to be carried by the elevator, and outputting the acquired data of the image,
wherein the data of the building includes a plurality of pieces of data including data of a region in which the building is to be built, and
in the selection, the elevator is selected using data generated by respectively assigning weights to the plurality of pieces of data of the building.
